(19) United States
(12) Patent Application Publication
(10) Pub. No.: US 2022/0300202 A1
(43) Pub. Date: Sep. 22, 2022

(54) MEMORY SYSTEM, METHOD OF CONTROLLING MEMORY SYSTEM, AND HOST DEVICE

(71) Applicant: Kioxia Corporation, Tokyo (JP)

(72) Inventors: Tomohiro IKEDA, Tokyo (JP); Hanz Vladimir Orina CABANES, Yokohama (JP); Taiki KANDA, Kawasaki (JP)

(73) Assignee: Kioxia Corporation, Tokyo (JP)

(21) Appl. No.: 17/349,128

(22) Filed: Jun. 16, 2021

(30) Foreign Application Priority Data
Mar. 19, 2021 (JP) 2021-045469

(51) Int. Cl. G06F 3/06

(52) U.S. Cl. CPC G06F 3/0659; G06F 3/0632; G06F 3/0653; G06F 3/0619; G06F 3/0679

(57) ABSTRACT

According to one embodiment, a memory system includes: a memory device; and a controller connectable to a host and configured to control the memory device in accordance with a firmware. The controller is configured to: receive a first command relating to the controlling of the memory device and a first file including a first flag from the host; execute a first sequence in accordance with a content of the first file; and after executing the first sequence, send a response including a notification of completion of the first sequence to the host. The first sequence includes: a first operation of executing update of the firmware when the first flag has a first value; and a second operation of sequentially executing second commands included in the first file when the first flag has a second value different from the first value.

### CROSS-REFERENCE TO RELATED APPLICATIONS

This application is based upon and claims the benefit of priority from Japanese Patent Application No. 2021-045469, filed Mar. 19, 2021, the entire contents of which are incorporated herein by reference.

### FIELD

Embodiments described herein relate generally to a memory system, a method of controlling a memory system, and host device.

### BACKGROUND

Memory systems, including NAND flash memory, are used in a variety of electronic devices. Such a memory system can be connected to the host device. The memory system executes processes in response to commands from the host device. The memory system may receive a general-purpose command instructing general-purpose processes, from the host device. That is, the host device can send the general-purpose command to the memory system.

### BRIEF DESCRIPTION OF THE DRAWINGS

FIG. 1 is a diagram for explaining a memory system of the first embodiment.

FIG. 2 is a diagram showing a configuration example of the memory system of the first embodiment.

FIG. 3 is a diagram showing an example of a circuit configuration of a memory cell array depicted in FIG. 2.

FIG. 4 is a diagram for explaining an overview of operation of the memory system of the first embodiment.

FIG. 5 is a diagram for explaining an operation example of the memory system of the first embodiment.

FIGS. 6, 7 and 8 are sequence diagrams showing an operation example of the memory system of the first embodiment.

FIG. 9 is a flowchart of the operation example of the memory system of the first embodiment.

FIG. 10 is a sequence diagram showing an operation example of a memory system of a second embodiment.

FIG. 11 is a sequence diagram showing an operation example of a memory system of a third embodiment.

### DETAILED DESCRIPTION

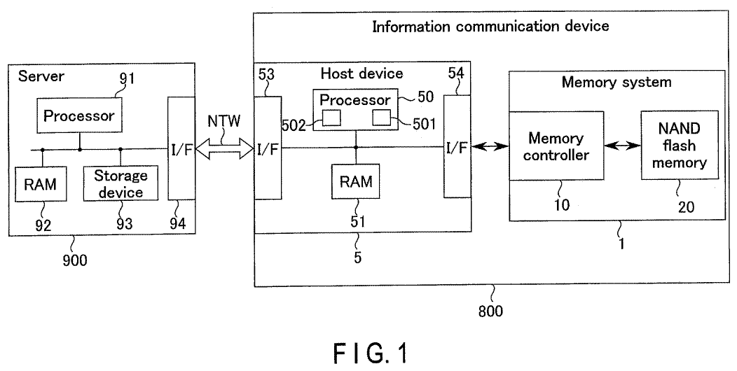

A memory system, a control method of the memory system, and a host device of an embodiment will be described with reference to FIGS. 1 to 11.

Hereinafter, the embodiments will be described in detail with reference to the accompanying drawings. In the description below, elements having the same functions and configurations will be denoted by the same reference symbols.

In the embodiments described below, when constituent elements denoted by reference symbols to which numbers/letters are attached at the end for discrimination (e.g., circuits, interconnects, various voltages and signals) do not have to be discriminated from each other, reference symbols without the numbers/letters at the end will be used.

In general, according to one embodiment, a memory system includes: a memory device; and a controller connectable to a host device and configured to control the memory device in accordance with a firmware, wherein the controller is configured to: receive a first command relating to the controlling of the memory device and a first file including a first flag from the host device; execute a first sequence in accordance with a content of the first file; and after executing the first sequence, send a response including a notification of completion of the first sequence to the host device; wherein the first sequence includes: a first operation of executing update of the firmware when the first flag has a first value; and a second operation of sequentially executing a plurality of second commands included in the first file when the first flag has a second value different from the first value.

### Embodiments

### (1) First Embodiment

A memory system, a control method of the memory system, and a host device of the first embodiment will be described with reference to FIGS. 1 to 9.

(a) Configuration Example

FIG. 1 is a diagram for illustrating the memory system of the present embodiment.

As shown in FIG. 1, a server 900 is connected to an information communication device 800 via a network NTW.

The server 900 includes a processor 91, a RAM 92, a storage device 93 and an interface circuit (referred to as an I/F as well) 94.

The processor 91 controls various processes (e.g., a calculation process and a data process) and operations performed in the server 900. The processor 91 can create a file including various data and/or information.

The RAM 92 functions as a work area for various data processes performed in the server 900. The RAM 92 temporarily stores a program (that is, software) and data used for various processes by the processor 91 (e.g., a result of a calculation process, data obtained in the middle of the calculation process, and/or parameters).

The storage device 93 stores various programs and various information.

The interface circuit 94 communicates with another device (the information communication device 800 in this example), based on a certain interface standard and/or a communication protocol used for the network NTW. For example, the interface circuit 94 sends a created file to the information communication device 800. The interface circuit 94 receives data from the information communication device 800.

The information communication device 800 includes a memory system 1 of the present embodiment, as well as the host device 5.

In the information communication device 800, the memory system 1 of the present embodiment writes data, reads data and erases data in the memory system 1, based on a request from the host device 5.

An internal configuration of the memory system 1 of the present embodiment will be described later.

The host device 5 includes a processor 50, a RAM 51 and interface circuits (referred to as I/Fs as well) 53 and 54.

The processor (hereinafter, referred to as a host processor as well) 50 controls various processes and operations of the host device 5.

The host processor 50 can issue (or generate) a command (hereinafter referred to as a host command) for requesting (e.g., commanding or instructing) various processes and operations for the memory system 1. The host processor 50 can generate a file according to the host command. In the description below, this file will be referred to as an input file or a host file.

A file is a data set including one or more data (information and parameters) used for processes and operations of the memory system 1. The file may include one or more commands (or data representing the commands) or an executable code. The file may include information indicative of a type of the file and/or characteristics of the file, such as flags and/or extensions. The file may be, for example, data written to the memory system 1.

For example, the host processor 50 includes a command generation unit (an example of a command generation circuit) 501 for generating the host command. The host processor 50 includes a file generation unit 502 (an example of a file generation circuit) for generating a file. The command generation unit 501 and the file generation unit 502 may be hardware (circuit) or software (program).

The RAM 51 functions as a work area for various data processes performed by the host processor 50.

The RAM 51 temporarily stores a program (that is, software), data (a result of a calculation process, data generated in the middle of the calculation process and parameters) used for various processes by the host processor 50.

The interface circuit 53 communicates with the server 900 via the network NTW, based on a certain interface standard and/or communication protocol. The interface circuit 53 outputs signals and data supplied from the server 900 to an internal bus in the host device 5.

The interface circuit 54 communicates with the memory system 1, based on a certain interface standard and/or a communication protocol.

The host command HCMD (command code) for the memory system 1 is based on the interface standard of the interface circuit 54. For example, the interface standard (or communication protocol) used in the interface circuit 54 is an SAS standard, an SATA standard, a PCIexpress (registered trademark) standard (hereinafter referred to as a PCIe standard), and an NVMexpress (registered trademark) standard (hereinafter referred to as an NVMe standard), Universal Flash Storage standard (hereinafter referred to as a UFS standard), or the like. An interface standard compliant with any of the interface standards exemplified herein or another interface standard may be used for the interface circuit 54.

The host device 5 can instruct the memory system 1 to execute various operations by using a command that is made public and/or a command that is private, both being based on the above interface standards.

The command that is made public (hereinafter referred to as a public command) is a command disclosed in specifications, technical data sheet, manual, etc. of the memory system 1. For example, the public command include a command that instructs the memory system 1 to perform various operations of the memory system 1 with respect to user data, such as writing data, reading data and invalidating or erasing data to the memory system 1.

A command that is not public (hereinafter referred to as a private command) is a command that is not disclosed in the specifications, the technical data sheet, the manual, etc. of the memory system 1. For example, the private command is a vendor-only (or developer-only) command based on a certain protocol. Examples of the private command include a command for debugging the memory system 1, a command for testing the memory system 1, a command for analyzing the memory system 1, a command for initializing various settings of the memory system 1, a command for receiving a log of an internal processing of the memory system 1, or the like.

It should be noted that like the public command, the private command is defined by the interface standard between the memory system 1 and the host device 5 (or the server 900).

In addition to the configuration described above, the host device 5 may further include a storage device (not shown), such as an HDD (Hard Disc Drive).

For example, the host device 5 (or the information communication device 800) is a personal computer, a smart phone, a feature phone, a mobile terminal (e.g., a tablet terminal), a game device, an in-vehicle device, a router, a base station, or the like.

The memory system 1 of the present embodiment includes a memory controller 10 and a NAND flash memory (hereinafter referred to simply as a flash memory as well) 20.

<Memory System>

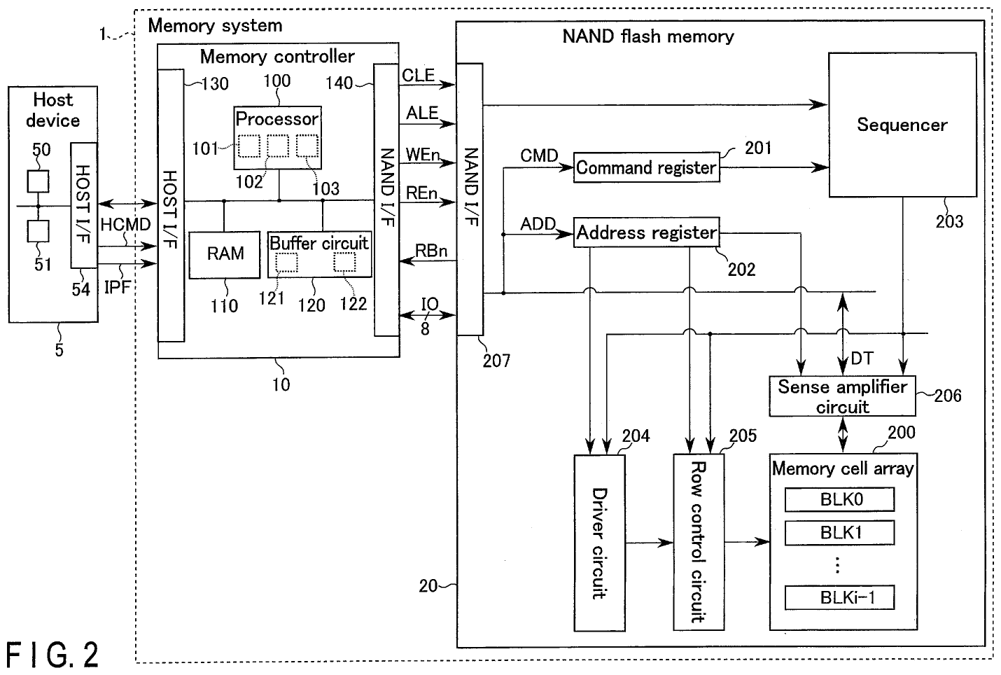

FIG. 2 is a diagram for illustrating a configuration example of the memory system of the present embodiment.

(Memory Controller)

Based on the request from the host device 5, the memory controller 10 instructs the NAND flash memory 20 to perform various processes and operations, such as writing data, reading data, and erasing data to the NAND flash memory 20.

The memory controller 10 includes a processor 100, a RAM 110, a buffer circuit 120, and interface circuits 130 and 140.

The processor 100 can command (or instruct) various processes and operations for the NAND flash memory 20. For example, the processor 100 can generate a command (hereinafter referred to as a controller command as well) indicative of an instruction to the NAND flash memory 20. For example, the processor 100 controls various processes and operations performed for the NAND flash memory 20, based on firmware stored in the memory system 1 (e.g., in a certain memory area of the NAND flash memory 20).

The processor 100 includes a CPU 101, an analysis unit (an example of an analysis circuit) 102, an execution unit (an example of an execution circuit) 103, etc. These components permit the processor 100 to have a function for executing public commands and private commands, a function for updating the firmware, etc.

The CPU 101 controls various processes executed in the processor 100 and various operations executed in the processor 100.

The analysis unit 102 analyzes the host command HCMD supplied from the host device 5.

The execution unit 103 executes an operation that is based on a result of an analysis process of the command HCMD.

The analysis unit 102 and the execution unit 103 may be configured by hardware (circuit) or software (program) as long as the functions of the units 102 and 103 can be realized.

The RAM 110 functions as a work area for various processes and operations of the processor 100 in the memory controller 10. The RAM 110 temporarily stores a program, data used for various processes performed by the processor 100 (a result of the calculation process, data generated in the middle of the calculation process, and parameters), etc. For example, the RAM 110 is accessed by the CPU 101 and the execution unit 103.

The RAM 110 may be a memory area (RAM) provided in the processor 100.

The buffer circuit 120 temporarily stores data transferred between the memory controller 10 and the host device 5 and data transferred between the memory controller 10 and the flash memory 20.

For example, the buffer circuit 120 includes a command buffer 121 and a data buffer 122.

The command buffer (an example of a command buffer circuit) 121 temporarily stores the host command HCMD.

The data buffer (an example of a data buffer circuit) 122 temporarily stores a file (an input file) IPF or data supplied from the host device 5. The input file IPF is a data set including one or more data and/or one or more commands (data indicative of commands). The input file IPF includes identification information such as flags.

The interface circuit (hereinafter referred to as a host interface circuit as well) 130 transfers data between the host device 5 and the memory controller 10, based on a certain interface standard. The interface standard (and the communication protocol) of the interface circuit 130 is the same standard (or compliant standard) as the interface standard of the interface circuit 54 of the host device 5.

The interface circuit (hereinafter referred to as a NAND interface circuit as well) 140 performs communications (e.g., data transfer) between the memory controller 10 and the NAND flash memory 20, based on the NAND interface standard.

When the memory controller 10 commands the NAND flash memory 20 to perform a certain operation, the memory controller 10 sends a data group including commands and address information (hereinafter referred to as a NAND command set as well) to the. NAND flash memory 20. When the memory controller 10 commands the NAND flash memory 20 to write data, the NAND command set further includes write data.

In addition to the above configuration, the memory controller 10 may include another configuration such as an ECC circuit (not shown).

(NAND Flash Memory)

The NAND flash memory 20 is a nonvolatile semiconductor memory device. The NAND flash memory 20 can store data substantially in a nonvolatile manner.

In the description below, the NAND flash memory 20 will be simply referred to as the flash memory 20.

The flash memory 20 includes, for example, a memory cell array 200, a command register 201, an address register 202, a sequencer 203, a driver circuit 204, a row control circuit 205, a sense amplifier circuit 206, an interface circuit (an example of an input/output circuit) 207, etc.

The memory cell array 200 stores data. A plurality of bit lines (not shown) and a plurality of word lines (not shown) are provided in the memory cell array 200. The memory cell array 200 includes one or more blocks BLK0 to BLKi-1 (i is an integer of 1 or more). Each block BLK (BLK0 to BLKi-1) is a set of a plurality of memory cells. The block BLK is used, for example, as a data erasing unit.

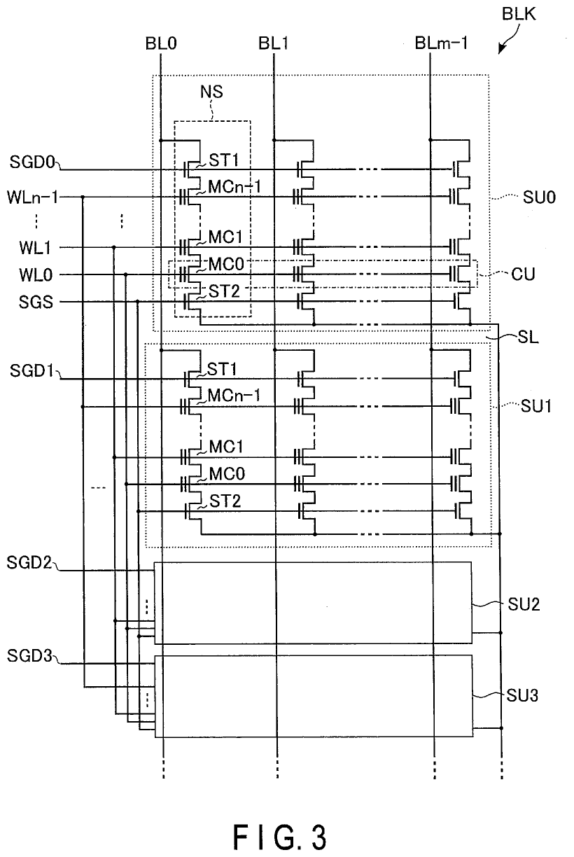

FIG. 3 is an equivalent circuit diagram showing an example of the circuit configuration of the memory cell array 200 of the NAND flash memory 20. In FIG. 3, one block BLK of a plurality of blocks BLK included in the memory cell array 200 is extracted and shown.

As in the example shown in FIG. 3, the block BLK includes, for example, four string units SU0, SU1, SU2 and SU3. Each string unit SU includes a plurality of memory cell strings (hereinafter referred to as NAND strings) NS. Each of the plurality of NAND strings NS is associated with the corresponding one of the plurality of bit lines BL0 to BLm-1 (m is an integer of 1 or more).

The NAND string NS includes a plurality of memory cells MC0 to MCn-1 and select transistors ST1 and ST2.

Memory cells (hereinafter referred to as memory cell transistors as well) MC (MC0 to MCn-1) are field effect transistors including a charge storage layer. The memory cell MC can store one or more bits of data substantially in a nonvolatile manner.

Each of the select transistors ST1 and ST2 is used to select a string unit SU during various operations.

In each NAND string NS, the memory cells MC0 to MCn-1 are connected in series between the source of the select transistor ST1 and the drain of the select transistor ST2. The control gates of the memory cells MC0 to MCn-1 in the same block BLK are commonly connected to the corresponding one of the plurality of word lines WL0 to WLn-1.

In each NAND string NS, one end (source) of the select transistor ST1 is connected to one end of the memory cells MC connected in series, and the drain of the select transistor ST1 is connected to the corresponding bit line BL. The gates of the select transistors ST1 are connected to the corresponding one of the plurality of select gate lines SGD.

In each NAND string NS, one end (source) of the select transistor ST2 is connected to the source line, and the other end (drain) of the select transistor ST2 is connected to the other end of the memory cells MC connected in series. The gates of the select transistors ST2 are connected to the select gate line SGS. For example, the sources of a plurality of select transistors ST2 in the same block BLK are commonly connected to one source line SL. The gates of the plurality of select transistors ST2 in the same block BLK are commonly connected to one select gate line SGS.

A unit constituted by a plurality of memory cell MC coupled to the common word line WL in one string unit SU are referred to, for example, as a cell unit CU. For example, when each of the memory cells MC stores one bit of data, one cell unit CU can store one page of data. When each of the memory cells MC stores two bits of data, one cell unit CU can store two pages of data. The “one-page data” is defined by, for example, the total amount of data stored in the cell unit CU constituted by the memory cells MC that store one bit of data.

The circuit configuration of the memory cell array 200 of the NAND flash memory 20 of the embodiment is not limited to the above configuration. For example, the numbers of memory cells MC and select transistors ST1 and ST2 in each NAND string NS can be designed to be arbitrary numbers. Also, the number of string units SU included in each block BLK may be designed to be an arbitrary number.

Turning back FIG. 2, a configuration other than that of the memory cell array 200 of the flash memory 20 will be described.

The command register 201 stores a command (controller command) CMD supplied from the memory controller 10. The controller command CMD is, for example, a signal set for causing the sequencer 203 to execute a read operation, write operation, an erase operation, etc.

The address register 202 stores an address information (hereinafter referred to as a selected address as well) ADD from the memory controller 10. The address information ADD includes, for example, a block address, a page address (word line address) and a column address. For example, the block address, page address, and column address are used to select a block BLK, a word line WL and a bit line BL, respectively. In the description below, the block selected based on the block address will be referred to as a selected block. The word line selected based on the page address will be referred to as a selected word line.

The sequencer 203 controls the operation of the internal circuits of the flash memory 20. For example, the sequencer 203 controls the driver circuit 204, based on the controller command CMD in the command register 201.

The driver circuit 204 outputs a plurality of voltages used for reading data (that is, a read operation), writing data (that is, a write operation), erasing data (that is, an erase operation), etc. For example, the driver circuit 204 applies a voltage to the interconnect corresponding to the selected word line, based on the page address in the address register 202.

The row control circuit 205 controls the operation related to rows of the memory cell array 200. The row control circuit 205 selects one block BLK in the memory cell array 200, based on the block address held in the address register 202. The row control circuit 205 transfers, for example, the voltage applied to the interconnect corresponding to the selected word line to the selected word line in the selected block BLK. The sense amplifier circuit 206 controls the operation related columns of the memory cell array 200. In the write operation, the sense amplifier circuit 206 applies a voltage to each of the bit lines provided in the memory cell array 200 in accordance with the write data DT supplied from the memory controller 10. In the read operation, the sense amplifier circuit 206 determines data stored in the memory cell, based on the potential of the bit line (or whether or not a current is generated). The sense amplifier circuit 206 transfers data based on this determination result to the memory controller 10 as read data DT.

The interface circuit 207 inputs and outputs various control signals and data between the memory controller 10 and the flash memory 20.

Communications between the NAND flash memory 20 and the memory controller 10 are supported by the NAND interface standard. For example, in the communications between the flash memory 20 and the memory controller 10, a command latch enable signal CLE, an address latch enable signal ALE, a write enable signal WEn, a read enable signal REn, a ready busy signal RBn, and input/output signal IO are used.

The command latch enable signal CLE is a signal indicating that the input/output signal IO received by the flash memory 20 is a controller command CMD. The address latch enable signal ALE is a signal indicating that the signal IO received by the flash memory 20 is address information ADD. The write enable signal WEn is a signal that instructs the flash memory 20 to input the input/output signal IO to the flash memory 20. The read enable signal REn is a signal that commands the flash memory 20 to output the input/output signal I/O to the memory controller 10.

The ready busy signal RBn is a signal that notifies the memory controller 10 whether the flash memory 20 is in the ready state or the busy state. The ready state is a state in which a command from the memory controller 10 is accepted. The busy state is a state in which the flash memory 20 does not accept a command.

The input/output signal IO may include a controller command CMD, address information ADD, data DT, etc. The input/output signal IO is, for example, a signal of 8-bit width (signal set).

The NAND flash memory 20 may have a control unit called a plane, by a configuration (control unit) including a memory cell array 200, a row control circuit 205 and a sense amplifier circuit 206. FIG. 2 shows an example in which the NAND flash memory 20 has one plane. It should be noted, however, the NAND flash memory 20 may include two or more planes. The configuration of the plane is not limited to the above configuration, and the plane is only required to include at least the memory cell array 200.

For example, the memory system 1 is an SSD (solid state drive), a memory card, a USB (universal serial bus) memory, a UFS device, or the like.

Instead of the NAND flash memory 20 described above, another type of nonvolatile or volatile memory device may be used in the memory system 1.

<Concept>

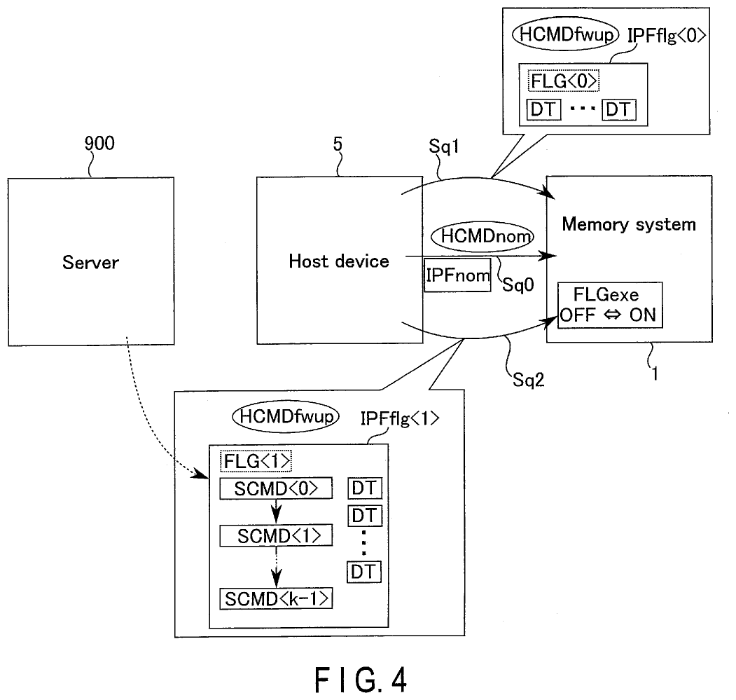

FIG. 4 is a schematic diagram for illustrating the basic concept underlying the memory system of the present embodiment.

As shown in FIG. 4, the memory system 1 of the present embodiment performs various processes and operations in accordance with a plurality of operation sequences (operation modes) Sq0, Sq1 and Sq2 commanded (requested and instructed) by the host device 5.

As described above, the memory system 1 of the present embodiment receives the host commands HCMD (HCMDfwup and HCMDnom) and input files IPF (IPFflg<0>, IPFflg<1> and IPFnom) from the host device 5. The memory system 1 of the present embodiment executes various processes and operations, based on the host commands HCMD and contents (or a content) of the input file IPF. For example, the host command HCMD includes a command relating to the controlling of the memory system 1 and/or the flash memory 20.

For example, the memory system 1 of the present embodiment receives a normal command HCMDnom, a firmware update command HCMDfwup, etc. as the host commands HCMD.

When the host device 5 requests that the memory system 1 provide an operation sequence using the normal command HCMDnom (hereinafter referred to as a normal command mode as well) Sq0, the host device 5 issues (generates and sends) the normal command HCMDnom to the memory system 1. The memory system 1 executes processes and operations in accordance with the normal command HCMDnom supplied from the host device 5.

The normal command HCMDnom is the public command mentioned above. The normal command HCMDnom is, for example, a command based on the interface standard (e.g., the above-mentioned PCIe standard or NVMe standard) used between the host device 5 and the memory system 1 or a command based on the specifications of the memory system 1. The normal command HCMDnom is a command for accessing data in the flash memory 20 for data writing, data reading and data erasing, or a command related to various settings and management of the flash memory 20 (e.g., a status read command or a ZQ command).

The host device 5 may send an input file IPFnom (e.g., write data, parameters, setting information, etc.) together with the normal command HCMDnom, in accordance with the operation requested for the memory system 1.

In the description below, the host command HCMD and input file IPF associated with the command HCMD are referred to as a host command set.

When the host device 5 requests the memory system 1 an operation sequence (hereinafter referred to as an FW update mode as well) Sq1 for updating the firmware of the memory system 1 (hereinafter referred to as FW as well), the host device 5 issues the firmware update command (hereinafter referred to as the FW update command as well) HCMDfwup to the memory system 1. The firmware update command HCMDfwup is a command for updating the firmware of the memory system 1. The FW update command HCMDfwup may be issued in response to a request from the server 900.

In the FW update mode Sq1, the host device 5 sends an input file (hereinafter referred to as an FW update file as well) IPFflg<0>, including data and information for updating the firmware, to the memory system 1 in accordance with the FW update command HCMDfwup. The FW update file IPFflg<0> includes various data DT and information used for updating the firmware. For example, the FW update file IPFflg<0> includes an identification flag FLG. In the FW update mode Sq1, the identification flag FLG has, for example, a first value (<0>).

The memory system 1 executes various processes and operations for updating the firmware by using the FW update file IPFflg<0>, based on the FW update command HCMDfwup supplied from the host device 5.

When the host device 5 requests the memory system 1 an operation sequence (hereinafter referred to as a command sequence mode) Sq2 for successively executing a plurality of commands SCMD (SCMD<0>, SCMD<1> and SCMD<k>), the host device 5 issues the FW update command HCMDfwup to the memory system 1.

In the command sequence mode Sq2, the host device 5 sends an input file (hereinafter referred to as a command sequence file as well) IPFflg<1> for the command sequence mode Sq2 to the memory system 1 in accordance with the FW update command HCMDfwup. At this time, the host device 5 attaches the identification flag FLG having a second value (<1>) different from the first value to the command sequence file IPFflg<1>.

When the command sequence mode Sq2 is executed, the memory system 1 receives the command sequence file IPFflg<1> with the identification flag FLG having the second value (<1>) from the host device 5, together with the FW update command HCMDfwup.

In the present embodiment, when the memory system 1 receives the FW update command HCMDfwup, the memory system 1 determines, based on the identification flag FLG, whether the operation sequence (operation mode or operation) to be executed is the FW update mode Sq1 or the command sequence mode Sq2.

In the present embodiment, the identification flag FLG attached to the input file IPF is information indicative of the type of input file IPF (operation sequence to be executed by the memory system 1).

When the operation sequence to be executed by the memory system 1 is the FW update mode Sq1 (when the input file IPF is the FW update file IPFflg<0>), the identification flag FLG has the first value (<0>).

When the operation sequence to be executed by the memory system 1 is the command sequence mode Sq2 (when the input file IPF is the command sequence file IPFflg<1>), the identification flag FLG has the second value (<1>) different from the first value.

When the execution of the FW update mode Sq1 is requested, the host device 5 (or the server 900) attaches the identification flag FLG<0> of the first value to the input file IPF. When the execution of the command sequence mode Sq2 is requested, the host device 5 (or the server 900) attaches the identification flag FLG<1> of the second value to the input file IPF.

For example, the identification flag FLG is a 1-bit or 2-bit signal.

The identification flag FLG may be attached to the input file IPF only when the command sequence mode Sq2 is executed. When the normal command mode Sq0 is executed, the identification flag FLG indicative of the normal command mode Sq0 may be sent from the host device 5 to the memory system 1 together with the host command HCMD.

In the description below, when the identification flag FLG is the first value (referred to as a first flag value as well), the identification flag FLG will be mentioned as being in the off state. When the identification flag FLG is the second value (referred to as a second flag value as well), the identification flag FLG will be mentioned as being in the on state.

The input file IPFflg<1> with the identification flag FLG in the command sequence mode Sq2 includes one or more commands SCMD (SCMD<0>, SCMD<1> and SCMD<k-1>) used in the command sequence mode Sq2 (k is an integer of 1 or more), various data DT and information, together with the identification flag FLG<1>. For example, the command SCMD may be data (program code) indicative of one or more commands to be executed.

The memory system 1 of the present embodiment executes a plurality of commands SCMD<0>, SCMD<1> and SCMD<k-1> included in the command sequence file IPFflg<1>, based on the FW update command HCMDfwup and the command sequence file IPFflg<1>.

For example, when the command sequence file IPFflg<1> is generated, the host device 5 (or the server 900) determines an execution order in which a plurality of commands SCMD<0>, SCMD<1> and SCMD<k-1> in the command sequence file IPFflg<1> are executed.

The memory system 1 sequentially executes a plurality of commands SCMD<0>, SCMD<1> and SCMD<k-1> in the determined execution order.

When each of the commands SCMD<0>, SCMD<1> and SCMD<k-1> is executed, the memory system 1 appropriately uses the data DT included in the command sequence file IPFflg<1>.

For example, the memory system 1 sets a flag (hereinafter, the execution flag) FLGexe indicating that the command sequence mode Sq2 is being executed to either the off state or the on state, in accordance with the determination result of the identification flag FLG. When the identification flag FLG has the first value (in the FW update mode Sq1), the memory system 1 sets the execution flag FLGexe to the off state. When the identification flag FLG has the second value (in the command sequence mode Sq2), the memory system 1 sets the execution flag FLGexe to the on state. At the end of the execution of the command sequence mode Sq2, the memory system 1 changes the execution flag FLGexe from the on state to the off state.

The server 900 may generate the input file (e.g., the command sequence file) IPFflg<1> including the identification flag FLG. The server 900 provides the host device 5 with the command sequence file IPFflg<1>.

The host device 5 generates the FW update command HCMDfwup in accordance with the command sequence file TPFflg<1> supplied from the server 900. The host device sends the FW update command HCMDfwup and the command sequence file IPFflg<1> supplied from the server 900 to the memory system 1 of the present embodiment.

As described above, the memory system 1 of the present embodiment can execute a plurality of operation sequences Sq0, Sq1 and Sq2. The memory system 1 of the present embodiment can execute the operation sequence in accordance with the identification flag FLG attached to input file. IPF among a plurality of operation sequences Sq1 and Sq2 in the sequence when the memory system 1 receives the FW update command HCMDfwup.

(b) Operation Example

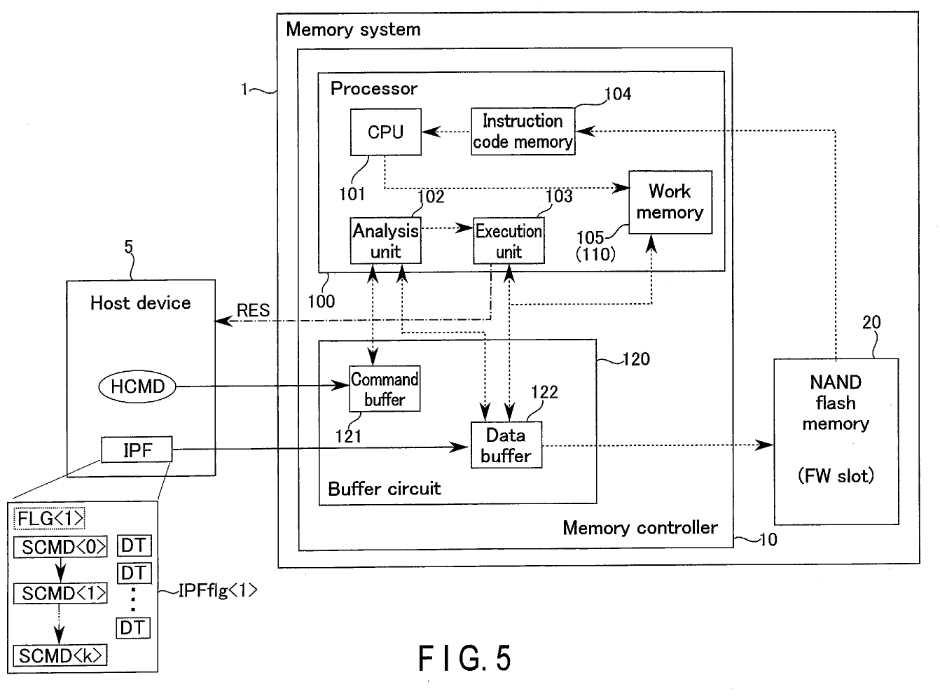

An operation example of the memory system of the present embodiment will be described with reference to FIGS. 5 to 9.

(b-1) Operation Sequence

The operation sequence of the memory system of the present embodiment will be described with reference to FIGS. 5 to 8.

As shown in FIG. 4 mentioned above, the memory system of the present embodiment can operate based on three operation sequences.

FIG. 5 is a diagram schematically showing a process flow illustrating how each of the components of the memory system of the present embodiment operates in each operation sequence.

As shown in FIG. 5, the host device 5 sends the host command HCMD to the memory system 1. The host device 5 sends the input file IPF to the memory system 1 in accordance with the operation requested to the memory system 1. As described above, the host device 5 attaches the identification flag FLG to the input file IPF in accordance with the operation sequence requested to the memory system 1.

The memory system 1 receives the host command HCMD and the input file IPF. The host command HCMD is stored in the command buffer 121 of the buffer circuit 120. The input file IPF is stored in the data buffer 122 of the buffer circuit 120.

In the memory system 1, the processor 100 executes the corresponding operation sequence (operation mode) in accordance with the host command HCMD in the command buffer 121.

As described above, the processor 100 includes a CPU 101, an analysis unit 102 and an execution unit 103. The processor 100 also includes an instruction code memory 104 and a work memory 105. The work memory 105 may be provided in the RAM 110.

The CPU 101 executes various processes and operations of the memory controller 10, various processes and operations for the flash memory 20, and various controls, based on the instruction code of the firmware FW.

The analysis unit 102 can access the host command HCMD in the command buffer 121. The host command HCMD is supplied from the command buffer 121 to the analysis unit 102.

The analysis unit 102 analyzes (e.g., decodes) the host command HCMD.

In the present embodiment, the analysis unit 102 can access the command SCMD included in the input file IPF in the data buffer 122. The command SCMD is supplied from the data buffer 122 to the analysis unit 102 under the control of the CPU 101 (or the execution unit 103).

The analysis unit 102 analyzes the command SCMD. For example, the analysis unit 102 can access the input file IPF and receive the command SCMD included in the input file IPF by controlling of the execution unit 103 in accordance with the identification flag FLG included in the input file IPF.

As described above, in the present embodiment, the analysis unit 102 can execute the analysis process related to the command HCMD in the command buffer 121 and the command SCMD in the data buffer 122.

The analysis unit 102 instructs the execution unit 103 to execute processes and operations that are based on the analysis results of the host command HCMD and command SCMD.

The execution unit 103 executes various processes and operations related to the host command HCMD and the command SCMD, in response to the instruction from the analysis unit 102. The execution unit 103 accesses the data buffer 122, the work memory 105 and the RAM 110 in accordance with the processes and operations to be executed. The execution unit 103 generates a response RES to the commands HCMD and SCMD when the processes and operations of the commands HCMD and SCMD are completed. The execution unit 103 outputs the generated response RES to the host device 5 or the work memory 105.

The execution unit 103 can access the flash memory 20.

The instruction code memory 104 stores an instruction code of the firmware of the memory system 1. The instruction code memory 104 is accessed from the CPU 101. The firmware is read from a firmware slot (e.g., the flash memory 20) when the memory system 1 is powered on. At this time, the instruction code of the firmware is stored in the instruction code memory 104.

The instruction code is a code (such as an opcode) indicative of a basic process (e.g., logical operation, arithmetic operation, data processing, etc.) to be executed in the memory system 1.

The work memory 105 functions as a work area which the CPU 101 uses for various data processes. The work memory 105 temporarily stores a program (or part of the program) and data (e.g., parameters being calculated and calculation results). The work memory 105 is accessed from the CPU 101 and the execution unit 103. The work memory 105 may be a memory area of the processor 100 or a memory area of the RAM 110.

For example, the instruction code memory 104 and the work memory 105 are volatile memories (e.g., DRAM or SRAM).

The flash memory 20 functions as the firmware slot (hereinafter referred to as an FW slot as well) in part of the memory area. The flash memory 20 stores firmware. When the firmware is updated, the current firmware in the flash memory 20 is rewritten with new firmware.

A nonvolatile memory device other than the flash memory 20 may be used as the firmware slot.

As described below, the memory system 1 of the present embodiment executes each of the operation sequences of the normal command mode Sq0, the FW update mode Sq1 and the command sequence mode Sq2, in response to the request made by the host device 5.

<Normal Command Mode>

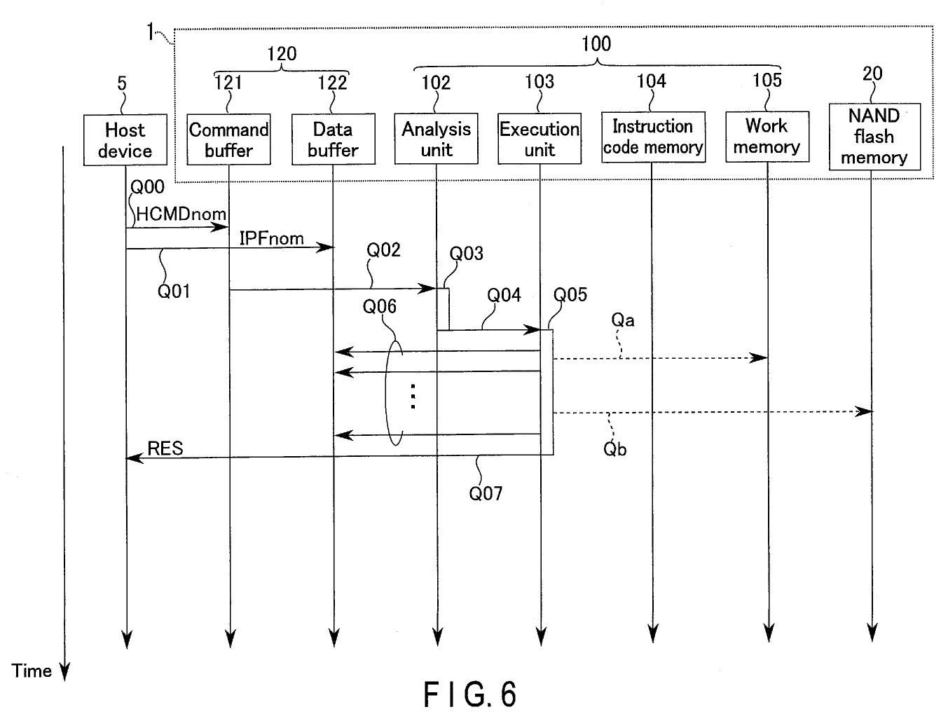

With reference to FIG. 6, a description will be given of various processes and operations which the memory system of the present embodiment performs in the normal command mode.

FIG. 6 is a sequence diagram showing a flow of processes which the components perform in the normal command mode Sq0 of the memory system 1 of the present embodiment.

<Q00, Q01>

As shown in FIG. 6, the host device 5 generates the host command HCMD in accordance with the process and operation requested to the memory system 1.

In the normal command mode Sq0, for example, when the host device 5 requests various operations of the memory system 1, the host processor 50 of the host device 5 generates the normal command HCMDnom. The normal command HCMDnom is a public command. The normal command HCMDnom is a data group defined based on the interface standard between the host device 5 and the memory system 1.

The host device 5 sends the normal command HCMDnom to the memory system 1 of the present embodiment via the above-mentioned interface circuit 54 as the host command HCMD (Q00).

The host device 5 causes the host processor 50 to generate the input file IPFnom in accordance with an operation of which the execution is requested. For example, in the normal command mode Sq0, the host device 5 does not attach the identification flag FLG indicative of the operation sequence to the input file IPFnom.

The host device 5 sends the input file IPFnom to the memory system 1 via the interface circuit 54 described above (Q01).

The input file IPFnom may not be generated, depending on the operation of which the execution is requested.

In this manner, when the host device 5 requests (commands, instructs) a certain process and operation of the memory system 1, the host device 5 sends the host command set to the memory system 1. In addition to the host command HCMD and the input file IPFnom, the host command set may further include address information indicative of an access destination in the memory system 1 and various information for executing the host command HCMD.

The memory system 1 receives the host command set via the host interface circuit 130 described above.

In the memory system 1, the host command HCMD is supplied to the command buffer 121, and the input file IPFnom is supplied to the data buffer 122.

<Q02, Q03, Q04>

In the memory system 1, the host command HCMD is input from the command buffer 121 to the analysis unit 102 by the CPU 101 (Q02).

The analysis unit 102 analyzes the normal command HCMDnom as the host command HCMD (Q03).

The analysis unit 102 instructs the execution unit 103 to execute various processes and operations, based on the analysis result of the normal command HCMDnom (Q04).

<Q05, Q06>

The execution unit 103 executes a plurality of processes and operations, based on the instruction supplied from the analysis unit 102 (Q05).

The execution unit 103 accesses data in the input file IPFnom of the data buffer 122 in accordance with the process and the operation to be executed (Q06).

For example, the execution unit 103 performs access (Qa) to the work memory 105 and/or access (Qb) to the flash memory 20 in accordance with the process and operation to be executed.

The operations and processes executed in the normal command mode Sq0 include writing data to the flash memory, reading data from the flash memory, erasing data in the flash memory, a patrol operation (refresh operation) or garbage collection, and an operation for circuit settings of the flash memory 20 (e.g., a calibration operation).

<Q07>

When the operation and process according to the normal command HCMDnom are completed in the memory system 1, the execution unit 103 outputs a response RES. The host device 5 receives the response RES from the memory system 1.

The response RES includes a notification of the completion of the operation sequence, read data, and/or information (e.g., status or parameter) indicative of the result of the process and operation executed in response to the host command HCMD.

The host device 5 executes various processes and operations for the server 900 or the memory system 1 or internal processes of the host device 5, based on the response RES.

When a plurality of commands are transferred from the host device 5 to the memory system 1, the memory system 1 may transfer the response RES to the host device 5 each time each command is executed.

In the manner described above, the operation sequence of the normal command mode Sq0 ends in the memory system 1 of the present embodiment.

<Firmware Update Mode>

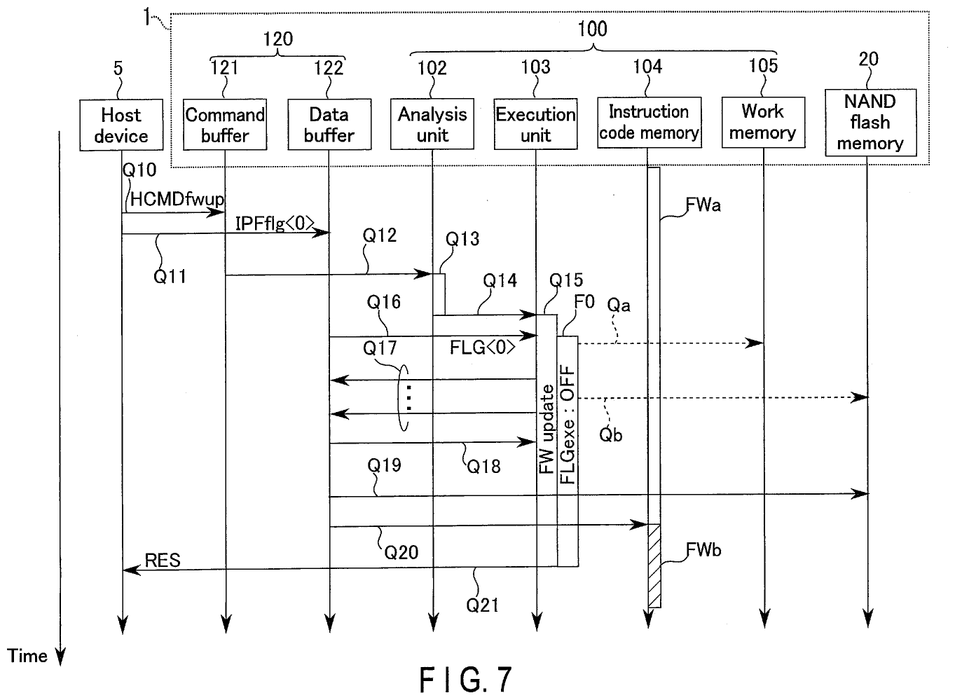

With reference to FIG. 7, a description will be given of various processes and operations which the memory system of the present embodiment performs in the FW update mode.

FIG. 7 is a sequence diagram showing a flow of processes which the components perform in the FW update mode Sq1 of the memory system 1 of the present embodiment.

<Q10, Q11>

As shown in FIG. 7, the host device 5 sends the host command set to the memory system 1. The host command set includes at least the host command HCMD and the input file IPF.

In the FW update mode Sq1, the host device 5 causes the host processor 50 to generate the FW update command HCMDfwup as the host command HCMD.

When the execution of the FW update mode Sq1 is requested, the input file IPF (the FW update file IPFflg<0>) includes various information related to the firmware update (hereinafter referred to as update information as well).

In the present embodiment, as shown in. FIG. 4 described above, when the execution of the FW update mode Sq1 is requested, the host device 5 causes the host processor 50 to attach the identification flag FLG to the input file IPF. The host device 5 sets the state of the identification flag FLG to a state indicative of execution of the FW update mode Sq1. The identification flag FLG has the first value (<0>). The value set to the identification flag FLG is, for example, a value indicated by 1 or 2 bits.

The FW update file IPFflg<0> may be generated by the server 900.

As described above, the host device 5 sends the FW update command HCMDfwup to the memory system 1 (Q10). The host device 5 sends the FW update file IPFflg<0> with the identification flag to the memory system 1 (Q11).

The memory system 1 receives the host command set. In the memory system 1, the FW update command HCMDfwup as the host command HCMD is supplied to the command buffer 121, and the input file IPFflg<0> including the identification flag FLG is supplied to the data buffer 122.

The memory system 1 operates using the instruction code in the instruction code memory 104, based on the 1firmware (current firmware) FWa read at the time of power-on.

<Q12, Q13, Q14>

The host command HCMD is input from the command buffer 121 to the analysis unit 102 (Q12).

In the memory system 1, the analysis unit 102 analyzes the host command HCMD supplied from the command buffer 121 (Q13). By analyzing the host command HCMD, the analysis unit 102 detects that the host command HCMD to be executed is the FW update command HCMDfwup.

The analysis unit 102 instructs the execution unit 103 to execute the FW update (Q14).

<Q15, Q16, Q17>

The execution unit 103 executes an operation in response to an instruction to execute the FW update command HCMDfwup from the analysis unit 102 (Q15).

In the present embodiment, the execution unit 103 accesses the input file IPFflg<0> in the data buffer 122 in accordance with the FW update command HCMDfwup from the analysis unit 102. The execution unit 103 confirms the state of the identification flag FLG in the input file IPFflg<0> (Q16).

When the identification flag FLG is indicative of the FW update file IPFflg<0> (execution of the FW update mode Sq1), the execution unit 103 detects the identification flag FLG<0> of the first value. As a result, the execution unit 103 executes the firmware update. In this case, the execution unit 103 sets the executing flag FLGexe to the off state (F0).

During the execution of the firmware update, the execution unit 103 accesses the FW update file IPFflg<0> in accordance with a progress of the firmware update (Q17). As a result, the execution unit 103 executes various processes and operations using the FW update file IPFflg<0>.

At the time of updating the firmware, the execution unit 103 may use data stored in the work memory 105 or the flash memory (FW slot) 20 (Qa, Qb).

<Q18, Q19, Q20>

In accordance with the progress of the FW update, the execution unit 103 uses the FW update file IPFflg<0> to perform verification of both the current firmware (firmware before the update) and the new firmware (firmware after the update) (Q18).

The execution unit 103 uses the. FW update file IPFflg<0> to make the FW firmware nonvolatile (Q19). For example, the execution unit 103 writes the new firmware and information on the firmware into a specific storage area of the flash memory 20 used as the FW slot.

The execution unit 103 rewrites an instruction code (execution code) using the FW update file IPFflg<0> (Q20). The execution unit 103 rewrites the instruction code based on the current firmware FWa stored in the instruction code memory 104 to the instruction code based on the new firmware FWb.

As a result, the instruction code in the instruction code memory 104 is updated from the instruction code of the firmware FWa before the update to the instruction code of the firmware FWb after the update.

By updating the instruction code, the memory system 1 of the present embodiment operates based on the new firmware (the firmware after the update) FWb.

Immediately after the update from the firmware Fwa to the new firmware FWb, the operation based on the previous firmware FWa may be continued without execution of an operation based on the new firmware FWb. In this case, the operation based on the new firmware FWb is executed at the next reset of the memory system 1 or the next startup of the memory system 1.

<Q21>

The execution unit 103 outputs a response RES related to the FW update command HCMDfwup. The memory system 1 sends the response RES to the host device 5.

The host device 5 receives the response RES from the memory system 1. This allows the host device 5 to detect a completion of the firmware update.

The host device 5 may notify the server 900 of the completion of the firmware update in the memory system 1 in response to the response RES.

For example, even if the firmware update fails, the execution unit 103 may send a response RES including error information to the host device 5.

In the manner described above, the firmware update sequence ends in the memory system 1 of the present embodiment.

<Command Sequence Mode>

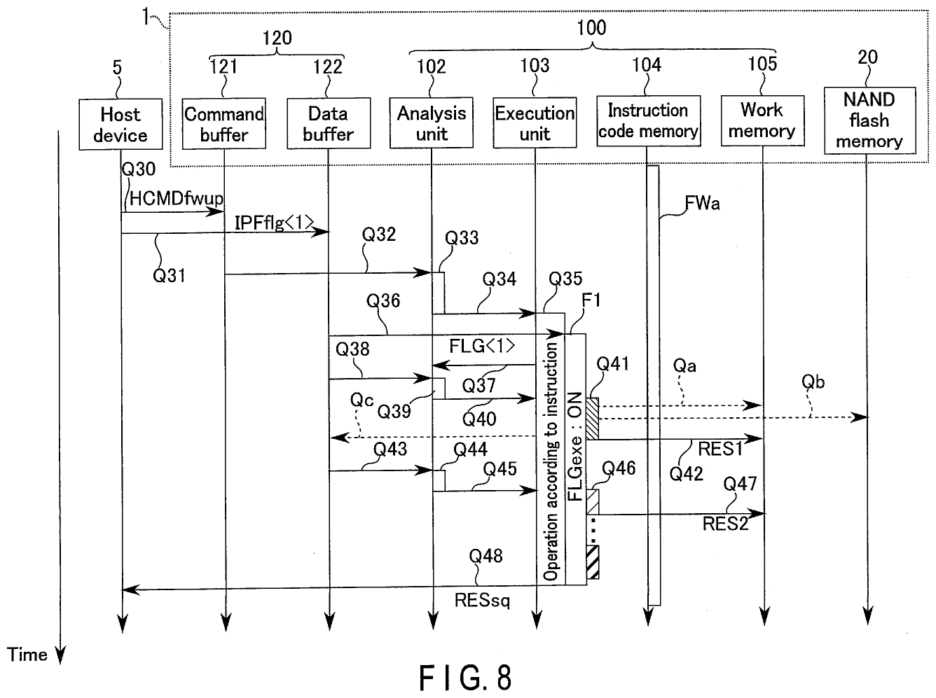

With reference to FIG. 8, a description will be given of various processes and operations which the memory system of the present embodiment performs in the command sequence mode.

FIG. 8 is a sequence diagram showing the flow of processes which the components perform in the command sequence mode Sq2 of the memory system 1 of the present embodiment.

<Q30, Q31>

As shown in FIG. 8, the host device 5 sends the host command set to the memory system 1, as in the above example.

When the host device 5 requests the memory system 1 to execute the command sequence mode Sq2, the host device 5 causes the host processor 50 to generate the FW update command HCMDfwup. The host device 5 sends the generated FW update command HCMDfwup to the memory system 1 as the host command HCMD (Q30).

In the present embodiment, when the execution of the command sequence mode Sq2 is requested, the host device 5 causes the host processor 50 to attach the identification flag FLG to the input file IPF, as shown in FIG. 4 mentioned above. The host device 5 sets the state of the identification flag FLG to a state indicative of the command sequence file IPFflg<1> (execution of the command sequence mode Sq2). For example, the identification flag FLG has the second value (<1>) different from the first value (<0>).

When the execution of the command mode Sq2 is requested, the host device 5 causes the host processor 50 to store a plurality of commands SCMD or data indicative of the plurality of commands in the input file IPF (the command sequence file IPFflg<1>), as shown in FIG. 4 mentioned above. One or more of the plurality of commands in the command sequence file IPFflg<1> may be the private commands. Alternatively, all commands in the command sequence file IPFflg<1> may be either the private commands or the public commands.

The host device 5 causes the host processor 50 to determine an execution order in which the plurality of commands SCMD stored in the command sequence file IPFflg<1> are executed. For example, host device 5 arranges the plurality of commands SCMD in the command sequence file IPFflg<1>, based on the execution order of the plurality of commands SCMD.

When the data indicative of the plurality of commands SCMD is stored in the command sequence file IPFflg<1>, the plurality of commands SCMD may be described in that data in the execution order of the commands.

As a result, the plurality of commands SCMD are executed in the specific execution order of the plurality of commands SCMD in the command sequence file IPFflg<1> when the analysis unit 102 (described later) accesses the input file IPF.

Each command SCMD in the command sequence file IPFflg<1> may have a code (or flag) indicative of the execution order. Alternatively, data indicative of the execution order of the plurality of commands SCMD may be stored in the command sequence file IPFflg<1> as information related to the command sequence mode Sq2.

The host device 5 causes the host processor 50 to store one or more data (e.g., setting information and parameters) used when the command sequence mode Sq2 is executed, into the command sequence file TPFflg<1>. For example, in the command sequence file IPFflg<1>, each of the plurality of data DT is associated with the corresponding one of the plurality of commands SCMD.

In this manner, the host device 5 generates the command sequence file IPFflg<1> having the identification flag FLG<1> as an input file IPF to be supplied to the memory system 1.

The host device 5 sends the generated command sequence file IPFflg<1> with the identification flag to the memory system 1 (Q31).

The memory system 1 receives the host command set. The FW update command HCMDfwup as the host command HCMD is stored in the command buffer 121. The command sequence file IPFflg<1> including the identification flag FLG is stored in the data buffer 122 as the input file IPF.

In the command sequence mode Sq2, a file (a command sequence file IPFflg<1>) including the identification flag FLG and a plurality of commands SCMD may be generated by the server 900. The server 900 provides the generated command sequence file IPFflg<1> to the host device 5.

The server 900 may provide the input file IPF for executing the command sequence mode Sq2 to the host device 5 without attaching the identification flag FLG. In this case, the host device 5 attaches the identification flag FLG<1> with a value indicative of the command sequence mode Sq2 to the file supplied from the server 900.

<Q32, Q33, Q34>

The FW update command HCMDfwup as the host command HCMD is transferred from the command buffer 121 to the analysis unit 102 (Q32).

The analysis unit 102 analyzes the host command HCMD (Q33). By the analysis of the host command HCMD, the analysis unit 102 detects that the host command HCMD is the FW update command HCMDfwup.

The analysis unit 102 instructs the execution unit 103 to perform processes and operations in accordance with the FW update command HCMDfwup (Q34).

<Q35, Q36, Q37>

The execution unit 103 executes an operation in response to an instruction to execute the FW update command HCMDfwup supplied from the analysis unit 102 (Q35).

In the present embodiment, the execution unit 103 accesses the input file IPFflg<1> in the data buffer 122 in response to the instruction supplied from the analysis unit 102, and confirms the identification flag FLG (Q36).

When the identification flag FLG indicates the command sequence file IPFflg<1> (when the identification flag FLG has the second value <1>), the execution unit 103 detects the identification flag FLG<1> of the second value. The execution unit 103 starts executing the command sequence mode Sq2.

The execution unit 103 sets the execution flag FLGexe to the on state when the command sequence mode Sq2 is executed (F1).

For example, the execution unit 103 notifies the analysis unit 102 (or CPU 101) that the identification flag FLG indicates the command sequence mode Sq2 (Q37). By the execution flag FLGexe in the on state, the analysis unit 102 (and the CPU 101) can recognize that the operation mode to be executed is the command sequence mode Sq2. The execution flag FLGexe may be sent from the execution unit 103 to the analysis unit 102 (and CPU 101), or may be stored in a register accessible to the analysis unit 102 (and CPU 101). For example, the execution flag FLGexe is a 1-bit or 2-bit signal. When the execution flag FLGexe is in the on state, the execution flag FLGexe has a third value. When the execution flag FLGexe is in the off state, the execution flag FLGexe has a fourth value different from the third value. In the FW update mode Sq1 and the normal command mode Sq0, the execution unit 103 sets the execution flag FLGexe to the off state (fourth value).

As described above, in the present embodiment, the identification flag FLG enables the memory system 1 (e.g., the processor 100) to recognize that the operation sequence to be executed is the command sequence mode Sq2 even if the host command HCMD is the FW update command HCMDfwup. For example, the operation mode of the memory system 1 according to the host command HCMD is changed from the FW command mode Sq1 to the command sequence mode Sq2 by checking the identification flag FLG.

<Q38, Q39, Q29>

In the command sequence mode Sq2, the execution unit 103 accesses the command sequence file IPFflg<1> in the data buffer 122, and sends one of the plurality of commands SCMD in the file IPFflg<1> to the analysis unit 102 (Q38).

The analysis unit 102 receives a first command SCMD<0> of the command sequence file IPFflg<1>. In the command sequence mode Sq2, the first command SCMD<0> is input to the analysis unit 102 by the execution unit 103.

As mentioned above, the execution order of the plurality of commands SCMD of the command sequence file IPFflg<1> is determined when the command sequence file IPFflg<1> is generated. Therefore, the execution unit 103 can send one of the plurality of commands to the analysis unit 102 in a specific execution order.

For example, the plurality of commands SCMD of the command sequence file IPFflg<1> are stored in a queue (or a stack) of the data buffer 122 according to the arranging order of the commands SCMD in the command sequence file IPFflg<1>. Alternatively, the codes of the plurality of commands are described in the data in the execution order of the commands.

In this manner, the plurality of commands SCMD are supplied to the analysis unit 102 in the execution order determined by the host device 5 (host processor 50).

The plurality of commands SCMD in the command sequence file IPFflg<1> may be received by the analysis unit 102 in accordance with whether or not the execution of the command sequence mode Sq2 (e.g., the on-state execution flag FLGexe) is detected without reference to the execution unit 103.

The analysis unit 102 analyzes the received commands SCMD (Q39).

The analysis unit 102 instructs the execution unit 103 to perform a process and/or operation in accordance with the commands, based on the analysis result of the commands SCMD (Q40).

The execution unit 103 executes processes and operations in accordance with the first command SCMD<0> (Q41). For example, in accordance with the first command SCMD, the execution unit 103 accesses the work memory 105, the flash memory 20 or the data buffer 122 (Qa, Qb, Qc).

The execution unit 103 completes the process and operation in accordance with the first command SCMD<0>. The execution unit 103 stores a response RES1 in accordance with the completion of the first command SCMD<0> into the work memory 105 (Q42).

When the response RES1 is stored in the work memory 105, an identification number may be attached to the response RES1 so that a correspondence between the first command SCMD<0> and the response RES1 can be shown, or the response RES1 may be stored at an address associated with the first command SCMD<0> in the work memory 105.

The execution unit 103 may notify the analysis unit 102 of the completion of the process and operation according to the first command. The execution period of each command SCMD may be managed based on the management of a time counter (not shown) of the CPU 101.

As a result, the analysis unit 102 can receive another command SCMD in the data buffer 122 after the process according to a certain command is completed.

<Q43, Q44, Q45, Q46>

After the process and operation according to the first command are completed, the execution unit 103 sends a second command SCMD<1>, which is to be executed after the first command SCMD<0>, from the data buffer 122 to the analysis unit 102 (Q43). Thus, the second command SCMD is supplied to the analysis unit 102.

The analysis unit 102 executes the analysis process of the second command (Q44). The analysis unit 102 sends an instruction based on the analysis result of the second command SCMD<1> to the execution unit 103 (Q45).

The execution unit 103 executes the process and operation according to the second command SCMD<1>, based on the instruction from the analysis unit 102 (Q46). As described above, the execution unit 103 accesses the data buffer 122, the work memory 105 or the flash memory 20 as appropriate.

When the process and operation according to the second command SCMD<1> is completed, the execution unit 103 stores the response RES2 according to the completion of the second command SCMD<1> into the work memory 105 (Q47).

Thereafter, processes and operations substantially the same as the processes and operations of Q38 to Q47 are executed for all of the plurality of commands SCMD in the command sequence file IPFflg<1>.

In this manner, the plurality of commands SCMD in the input file IPF are executed in a specific order.

If, in the command sequence mode Sq2, the processes and operations of the command SCMD are not completed within the period set for the time counter, information indicative of an execution error may be added to the responses RES1 and RES2, or a response indicative of the execution error may be sent to the host device 5 during the execution of the command sequence mode Sq2. If, in the command sequence mode Sq2, an execution error occurs due to the time out of execution, the execution of the command sequence mode Sq2 may be suspended or ended.

<Q48>

When all executions of the plurality of commands SCMD in the command sequence file IPFflg<1> are completed, the execution unit 103 transfers a response RESsq according to the command sequence mode Sq2 to the host device 5.

The host device 5 receives the response RESsq.

As a result, the host device 5 detects the completion of the processes and operations of the plurality of commands SCMD in the command sequence file IPFflg<1>. The host device 5 can receive the process result (e.g., log data) of the command sequence mode Sq2 included in the response RESsq.

If, in the command sequence mode Sq2, an execution error of the command SCMD occurs, the memory system 1 may transfer the execution error of the command sequence mode Sq2 to the host device 5 as a response RESsq.

It should be noted that responses RES1 and RES2 of the commands SCMD may be transferred to the host device 5 at the time of the completion of execution of commands SCMD, without being stored in the work memory 105.

The host device 5 can read the responses RES1 and RES2 stored in the work memory 105 from the memory system 1.

As can be seen from this, even if the host command HCMD from the host device 5 is the FW update command HCMDfwup, the memory system 1 of the present embodiment can execute an operation sequence (the command sequence mode Sq2 in the present embodiment) different from the update of the firmware, based on the identification flag FLG in the input file IPF.

As described above, the command sequence mode Sq2 is completed in the memory system 1 of the present embodiment.

(b-2) Process Flow

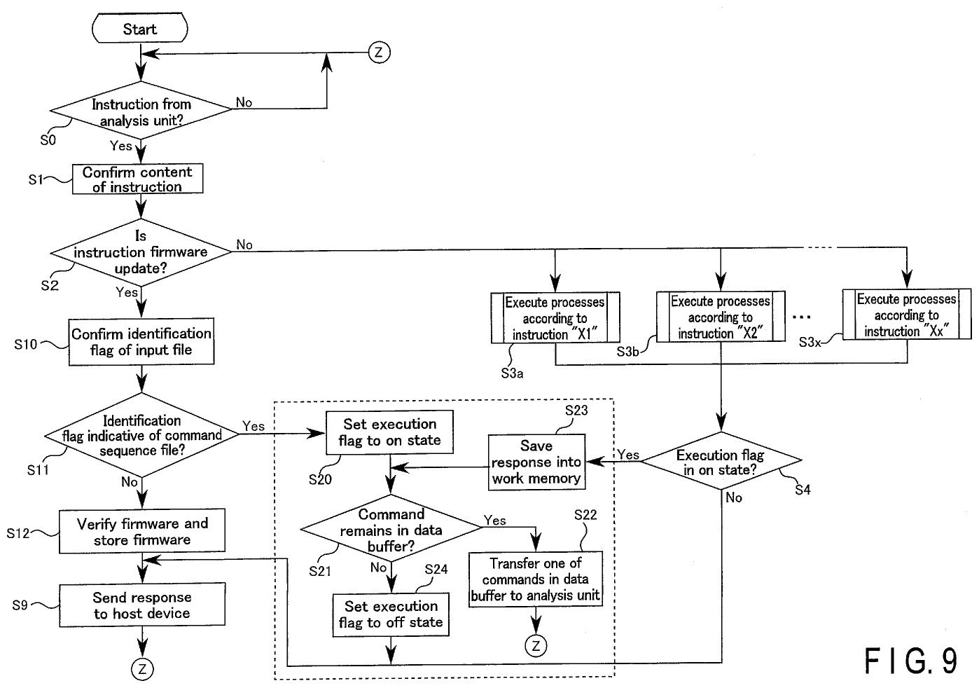

The process flow of the memory system 1 of the present embodiment will be described with reference to FIG. 9.

FIG. 9 is a flowchart for illustrating the process flow of the memory system of the present embodiment. In the description below, not only FIG. 9 but also FIGS. 1 to 8 will be referred to as appropriate, for illustrating the process flow of the memory system of the present embodiment.

As will be described below, the memory system 1 of the present embodiment executes the above-mentioned plurality of operation sequences.

<S0>

When the memory system 1 of the present embodiment is turned on, the memory system 1 boots the firmware. Various information regarding the firmware are read from the NAND flash memory (FW slot) 20 to the processor 100 of the memory controller 10. The instruction codes of the firmware are stored in the instruction code memory 104 in the processor 100.

In the memory system 1, the processor 100 causes the CPU 101, the analysis unit 102 and the execution unit 103 to control various internal processes of the memory controller 10 and various processes and operations of the flash memory 20.

In the processor 100, the CPU 101 confirms whether or not there is an operation instruction based on the analysis result of the analysis unit 102.

If there is no instruction from the analysis unit 102 (No in S0), the memory system 1 (memory controller 10) is in the standby state (or the internal process state).

At a certain timing, the host device 5 sends a host command set to the memory system 1 of the present embodiment.

The memory system 1 of the present embodiment receives the host command set. In the memory controller 10, the CPU 101 stores the host command HCMD included in the host command set into the command buffer 121. Also, the CPU 101 stores the input file IPF into the data buffer 122.

The analysis unit 102 analyzes (decodes) the host command HCMD input from the command buffer 121. In the processor 100, the analysis unit 102 sends an instruction according to the analysis result of the host command HCMD to the execution unit 103 under the control of the CPU 101.

<S1, S2>

If there is an instruction from the analysis unit 102 to the execution unit 103 (Yes in S0), the CPU 101 (or the execution unit 103) confirms the content of the instruction from the analysis unit 102 (S1).

The CPU 101 (or the execution unit 103) determines whether or not the instruction from the analysis unit 102 is a firmware update (S2).

<S3a, S3b, . . . , S3x>

When the instruction from the analysis unit 102 is not the firmware update (No in S2), the execution unit 103 executes various processes (and operations) in response to the instructions “X1”, “X2”, . . . , “Xx” from the analysis unit 102.

When the operation sequence to be executed is the normal command mode Sq0, the execution unit 103 execute various processes, based on the instructions “X1”, “X2”, . . . , “Xx”, as shown in FIG. 6 above.

<S4>

After the execution unit 103 completes various the processes and operations in response to the instructions from the analysis unit 102, the CPU 101 (or the execution unit 103) checks and determines whether the execution flag (FLGexe) is in the on state.

As described above, the execution flag FLGexe is internal information indicative of whether or not the operation sequence to be executed in the memory system 1 is the command sequence mode Sq2.

If the operation sequence to be executed is not the command sequence mode Sq2, the execution flag FLGexe is in the off state.

When the execution flag FLGexe is in the off state (when the execution flag FLGexe has the fourth value), the process of the memory system 1 proceeds to S9. The process performed in the memory system 1 when the execution flag FLGexe is in the on state will be described later.

<S9>

When the execution flag FLGexe is in the off state (No in S4), the CPU 101 causes the execution unit 103 to transfer the response to the host command HCMD to the host device 5.

Based on the response, the host device 5 detects that the sequence according to the host command HCMD has been completed in the memory system 1. For example, the host device 5 may transfer a notification (information) indicative of the completion of the sequence to the server 900.

Thereafter, the process performed in the memory system 1 proceeds to a process Z (that is, a process S0).

<S10, S11>

When the instruction from the analysis unit 102 is a firmware update (Yes in S2), the CPU 101 (or execution unit 103) checks the identification flag FLG of the input file IPF (S10). For example, the execution unit 103 accesses the data buffer 122 under the control of the CPU 101 and checks the status (that is, the flag value) of the identification flag FLG in the input file IPF corresponding to the instruction (host command HCMD).

The execution unit 103 determines whether or not the identification flag FLG indicates the command sequence file IPFflg<1> (S11).

<S12>

When the identification flag FLG does not indicate that the input file IPF is the command sequence file IPFflg<1> (No in S11), the execution unit 103 executes various processes and operations for firmware update, using the input file IPF (the FW update file IPFflg<0> in the present embodiment) by the operation sequence of the FW update mode Sq1, as shown in FIG. 7 above.

The execution unit 103 uses the FW update file IPFflg<0> in the data buffer 122 to verify the firmware and store the firmware (nonvolatilization).

As a result, the instruction code in the instruction code memory 104 is rewritten and replaced with a new instruction code based on the FW update file IPFflg<0>.

In this manner, the firmware update in the memory system 1 is completed.

Thereafter, the memory system 1 executes various operations, based on the updated firmware.

<S9>

After the firmware is updated, the CPU 101 causes the execution unit 103 to send a response to the FW update command HCMDfwup to the host device 5. Thereafter, the internal process of the memory system 1 proceeds to the process Z (that is, the process S0).

The host device 5 receives the response from the memory system 1 (the execution unit 103). For example, the host device 5 can notify the server 900 of the completion of firmware update in response to the response.

<S20>

When the identification flag FLG indicates that the input file IPF is the command sequence file IPFflg<1> (Yes in S11), the execution unit 103 executes various processes of the command sequence mode Sq2 under the control of the CPU 101 described above.

The execution unit 103 sets the execution flag FLGexe to the on state. For example, the value of the execution flag FLGexe changes from the fourth value to the third value.

<S21>

In the processor 100, the execution unit 103 (or the CPU 101) checks whether or not a command (data indicative of the command to be executed) of the command sequence file IPFflg<1>, which is the input file IPF, exists in the data buffer 122.

<S22>

If one or more commands exist in the data buffer 122 (Yes in S21), the execution unit 103 (or CPU 101) transfers one of the commands SCMD to the analysis unit 102.

As described above, the execution order of the plurality of commands SCMD of the command sequence file IPFflg<1> is determined in advance. For example, the plurality of commands are stored in a queue of the data buffer 122 in a specific order, or the execution order is indicated by data. Therefore, in the transfer of the commands SCMD from the data buffer 122 to the analysis unit 102, one command SCMD is transferred to the analysis unit 102, based on the execution order of the commands SCMD.

As a result, at the start of the command sequence mode Sq2, the command SCMD1 which is included in the plurality of commands SCMD in the command sequence file IPFflg<1> and which should be executed first in the command sequence is supplied to the analysis unit 102.

The process in the memory system 1 proceeds to the process Z (that is, the process S0).

<S0, S1, S2>

In the command sequence mode Sq2, the analysis unit 102 analyzes the command SCMD supplied in S22. The analysis unit 102 outputs an instruction to execute the command SCMD, based on the analysis result.

When an instruction according to the command SCMD is supplied from the analysis unit 102 (Yes in S0), the execution unit 103 determines whether or not the instruction from the analysis unit 102 is an instruction for the firmware update (S1, S2).

It should be noted that when the command sequence mode Sq2 is being executed (when the execution flag FLGexe is in the on state), the instruction from the analysis unit 102 is an instruction based on the command SCMD in the command sequence file IPFflg<1>, not an instruction based on the FW update command HCMDfwup.

Therefore, the process in the memory system 1 after S22 proceeds from the process in S2 to the process in S3 (S3a, S3b, . . . S3x).

<S3, S4>

When the command sequence mode Sq2 is being executed, the execution unit 103 executes the processes and operations according to the instruction (analysis result) from the analysis unit 102, as shown in FIG. 9 above (S3).

The CPU 101 (or the execution unit 103) determines whether or not the execution flag FLGexe is in the on state after the processes and operations are completed (S4).

As described above (the process S20), the execution flag FLGexe is set to the on state when the command sequence mode Sq2 is being executed.

Therefore, at the time of the command sequence mode Sq2, the process in the memory system 1 proceeds from the process S4 to the process S23.

<S23>

When the execution flag FLGexe is in the on state (Yes in S4), the execution unit 103 saves the response regarding the executed processes and operations (commands) into the work memory 105, as shown in FIG. 9 above.

After saving the response in the work memory 105, the execution unit 103 determines whether a command exists in the data buffer 122 (S21). When the command to be executed in the command mode Sq2 exists (remains) in the data buffer 122 (Yes in S21), the process in the memory system 1 proceeds to the process Z and the process S0, S1, S2, S3, S4 and S23 are executed, as in the above process.

With respect to a plurality of commands in the command sequence file IPFflg<1>, the response corresponding to the first command is saved, and then the CPU 101, analysis unit 102 and execution unit 103 execute the process and operation related to the command SCMD2 which are included in the plurality of commands and which should be executed second, based on the execution order of the commands.

This process is repeatedly executed by the CPU 101, the analysis unit 102 and the execution unit 103 in the processor 100, until all the commands in the command sequence file IPFflg<1> are executed.

<S24>

When a command to be executed in the command sequence mode Sq2 does not exist (remain) in the data buffer 122 (No in S11), this indicates that all the commands to be executed in the command sequence mode Sq2 have been completed.

In this case, the execution unit 103 sets the execution flag FLGexe related to the command sequence mode Sq2 to the off state. For example, the value of the execution flag FLGexe changes from the third value to the fourth value.

Thereafter, the execution unit 103 sends one or more responses RESsq related to the execution of the command sequence mode Sq2 to the host device 5 (S9).

As a result, the memory system 1 can provide the host device 5 with a process result (e.g., log) of a plurality of commands executed in the command sequence mode Sq2.

After the transfer of the response, the process in the memory system 1 proceeds to the process Z, as described above.

As described above, the memory system 1 of the present embodiment can execute a plurality of operation sequences, based on various flags FLG and FLGexe applied to the memory system 1 and in accordance with the command and input file TPF supplied from the host device 5.

(c) Summary

A memory system may execute a plurality of commands in a specific order so as to analyze a defect (a fault, a flaw) of the memory system, change the settings of the memory system, etc.

When the plurality of commands are executed in the specific order for the execution of a certain operation sequence, an execution error may occur due to the user's processing of the memory system. For example, the command execution order may be incorrect, the command may be omitted and/or data that should be used may be incorrect.

When an operation sequence including a plurality of commands to be executed in a specific order is executed using special software (e.g., bridge firmware) or a special command, the special software and the special command may not perform the desired process or operation in the environment of the user.

For example, when the bridge firmware executes an operation sequence that includes a plurality of commands, the bridge firmware may not be able to execute the plurality of commands, like the firmware used in the memory system. Thus, a time and a cost are incurred to verify the process and operation of the bridge firmware.

For example, when an operation sequence including a plurality of commands is executed by a special command, it may happen that the special command is not supported by the memory system (host device or flash memory).

The memory system 1 of the present embodiment executes an operation sequence including a plurality of commands, based on the firmware update command HCMDfwup, which is a general-purpose command.

The firmware update command HCMDfwup is supported by almost all memory systems (or host devices). Therefore, almost all memory systems have the firmware update function.

The firmware update is performed in a unified order, based on the specifications of the interface standards (and communication protocols) used in the memory system.

Thus, the memory system 1 of the present embodiment can execute the processes and the operations according to a plurality of commands SCMD, based on the determined execution order, without using a special command/or special software.

The memory system 1 of the present embodiment executes the operation sequence including a plurality of commands SCMD according to the firmware update command HCMDfwup, by using the file (data) IPF including the identification flag FLG.

The file IPF including the identification flag FLG includes a plurality of commands SCMD to be executed (and information indicative of the execution order of the plurality of commands).

The identification flag FLG indicates whether the operation to be executed in accordance with the firmware update command HCMDfwup is firmware update or execution of the plurality of commands SCMD in the file IPF.

As a result, the memory system 1 of the present embodiment can specify one operation sequence to be executed from among a plurality of operation sequences with no need to perform complicated analysis, when the firmware update command HCMDfwup is received.

The file IPF including the identification flag FLG is created, for example, by the host device 5 or the server 900 and provided to the memory system 1. For example, the identification flag FLG is attached by the host device 5 or the server 900.

As described above, the memory system 1 of the present embodiment can successively perform processes and operations according to a plurality of commands SCMD based on a specific execution order, without necessitating an excessive cost and time and without excessively changing the specifications of the memory system 1.

Therefore, the memory system 1 of the present embodiment can suppress an occurrence of an execution error of the operation sequence.

As described above, the host device 5 and the server 900 of the present embodiment can create and provide the update command HCMDfwup and the file IPF including the identification flag FLG. Thus, the host device 5 and the server 900 of the present embodiment can reduce execution errors in an operation sequence of the memory system 1.

As described above, the memory system 1 of the present embodiment can improve the functions (quality, characteristics, reliability, etc.) of the memory system.

### (2) Second Embodiment

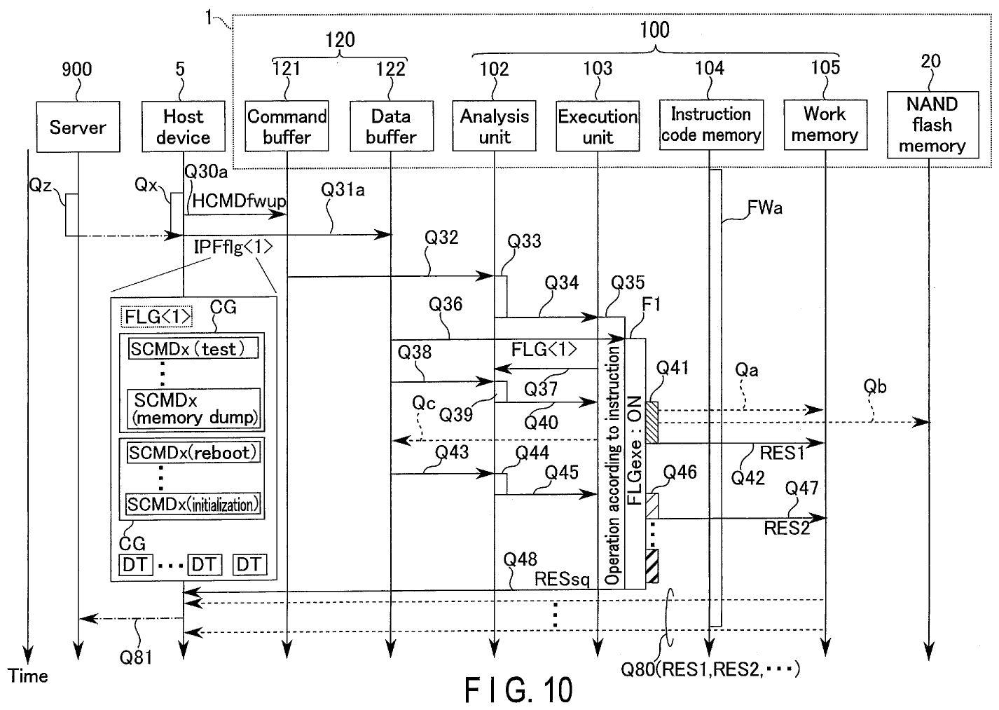

A memory system of the second embodiment will be described with reference to FIG. 10.

As described above, the memory system 1 of the first embodiment can execute an internal process of the memory system 1 in a specific order by using the command sequence mode Sq2. The various settings of the memory system 1 can be changed by the command sequence mode Sq2.

For example, when the internal state of the memory system 1 is set to the state that is before installation of various programs and applications (e.g., the state at the time of shipment from the factory), a special command (e.g., the private command) that is hard for the user to obtain and/or use may be used.

The execution order of processes and operations using private commands tends to be complicated.

As will be described below, the failure to change the settings of memory system 1 can be suppressed by executing the command sequence mode Sq2 using the input file IPF including a plurality of private commands.

FIG. 10 is a sequence diagram for illustrating the command sequence mode used in the memory system of the present embodiment. FIGS. 1 to 9 described above will be also referred to as appropriate.

It should be noted that, based on the process flow shown in FIG. 9 above, a plurality of operation sequences that are executable by the memory system 1 of the present embodiment are controlled.

<Q30a, Q31a>

As shown in FIG. 10, the host device 5 sends the firmware (FW) update command HCMDfwup and the command sequence file IPFflg<1> to the memory system 1 of the present embodiment. The memory system 1 is set to be executable the process flow shown in FIG. 9 based on the firmware read at the time of power-on.

The command sequence file IPFflg<1> includes the identification flag FLG and various data DT such as one or more command SCMDx, parameters and configuration information.

The identification flag FLG has a value <1> (e.g., the second value) indicative of the command sequence file IPFflg<1> (execution of the command sequence mode Sq2).

Each command SCMDx may include the private command (e.g., a vendor-only command). The command SCMDx is a command for performing one of: the execution of a test mode or a debug mode; the deletion of internal pointers; the formation of a file (memory dump) related to data in the memory system 1 (e.g., data in the RAM 110, the work memory 105 and/or the flash memory 20); the reboot of the memory system 1; the acquisition of the log in the memory system 1; the deletion of the information in the memory system 1; the initialization of the memory system 1, etc.

For example, one or more groups CG including a plurality of commands SCMDx may be formed in the command sequence file IPFflg<1> such that a plurality of commands SCMDx are executable in a specific order.

For example, the command sequence file IPFflg<1> including the private command is created by the process Qx of the host device 5 or the process Qz of the server 900.

When the server 900 creates the command sequence file IPFflg<1>, the command sequence file IPFflg<1> created by the server 900 is provided to the host device 5 (information communication device 800).

The memory system 1 of the present embodiment receives an FW update command HCMDfwup and the command sequence file IPFflg<1> as the input file IPF. The FW update command HCMDfwup is supplied to the command buffer 121. The command sequence file IPFflg<1> is supplied to the data buffer 122.

<Q32 to Q47>

Thereafter, when the memory system 1 receives the FW update command HCMDfwup, the execution unit 103 starts executing processes and operations in response to the instruction of the FW update command HCMDfwup supplied from the analysis unit 102 in the same manner as in the processes shown in FIGS. 8 and 9 described above (Q33 to Q35).

In response to the firmware update instructions (S0 to S2 in FIG. 9), the execution unit 103 confirms the identification flag FLG of the input file IPF in the data buffer 122, as shown in S10 in FIG. 9 (Q36).

When the identification flag FLG has a value (<1>) indicative of the command sequence file IPFflg<1> (Yes in S11 shown in FIG. 9), the execution unit 103 (or the CPU 101) executes various processes and operations by using the commands and data included in the command sequence file IPFflg<1> in the command sequence mode Sq2.

As shown in S20 in FIG. 9, the execution unit 103 sets the execution flag FLGexe to the on state, based on the confirmation result of the identification flag FLG (F1).

As shown in S0 to S4 and S21 to S24 in FIG. 9, the analysis unit 102 and the execution unit 103 sequentially executes a plurality of commands SCMDx (or a group CG including the plurality of command SCMDx) included in the command sequence file IPFflg<1> in a specific order (Q38 to Q47).

In the processor 100, the CPU 101, the analysis unit 102 and the execution unit 103 repeat the above operation until all of the plurality of commands SCMDx in the command sequence file IPFflg<1> are completed. As a result, the settings of the memory system 1 is changed.

<Q48, Q80, Q81>

After processes of all the commands in the command sequence file IPFflg<1> have been completed, the execution unit 103 outputs a response RESsq (or a plurality of responses in the work memory 105). The response RESsq is transferred from the memory system 1 to the host device 5.

In the transfer of the response during the execution of the command sequence mode Sq2, the execution unit 103 (or the CPU 101) may send all responses stored in the work memory 105 (responses corresponding to a plurality of commands SCMD executed in the command sequence mode Sq2) to the host device 5 (Q80). Alternatively, the execution unit 103 (or the CPU 101) may prepare one response, based on the plurality of responses stored in the work memory 105.

The host device 5 analyzes the response RESsq (and data) sent from the memory system 1.

The response RESsq allows the host device 5 to detect the execution result of the operation sequence using the command sequence file IPFflg<1>. For example, the host device 5 can detect that the state of the memory system 1 is set to the desired state (e.g., the state of shipping from the factory).

If a command execution error occurs in the command sequence mode Sq2, the host device 5 can detect by the response RES that an execution error of the command SCMDx of the command sequence file IPFflg<1> occurs.

The host device 5 may further transfer the response RESsq from the memory system 1 or the plurality of responses from the work memory 105 to the server 900 (Q81).

As described above, the memory system 1 of the present embodiment can change the settings of the memory system 1 in the command sequence mode Sq2 by using the command sequence file IPFflg<1> including the identification flag FLG.

As described above, the memory system 1 of the second embodiment can improve the functions (quality, characteristics, reliability, etc.) of the memory system.

### (3) Third Embodiment

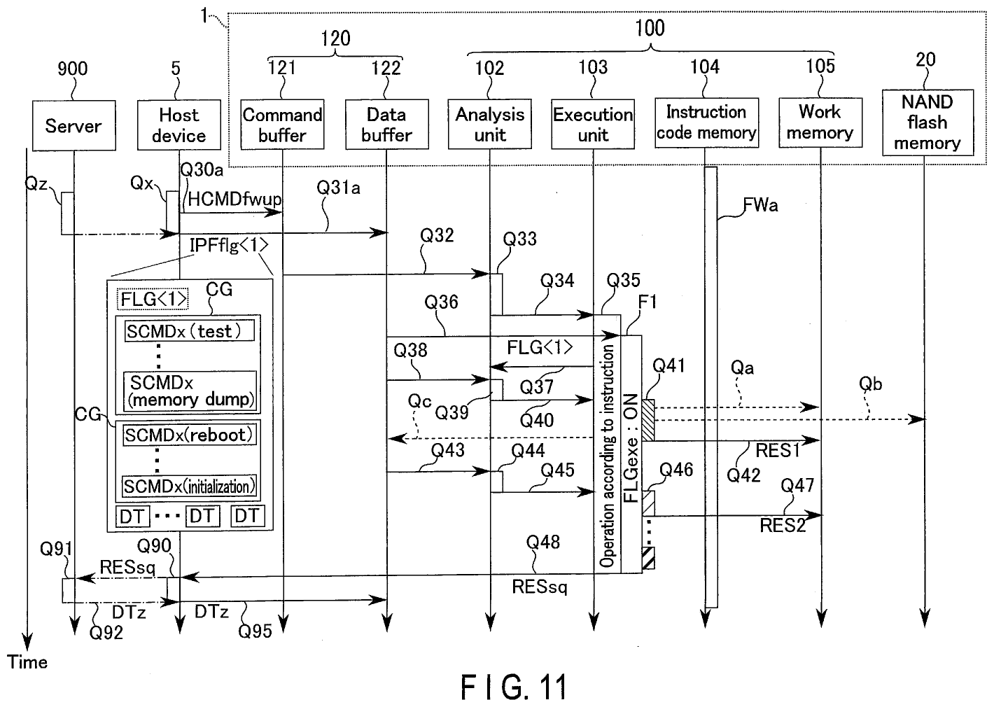

The memory system of the third embodiment will be described with reference to FIG. 11.

When a defect of the memory system 1 occurs when a user (client) uses the memory system 1, analysis of the operating status (log) of the memory system 1 may be executed to get rid of the defect.

The acquisition of the log of the memory system 1 includes execution of a command which is hard for the user to receive and use and execution of various processes in a specific order.

As will be described below, the memory system 1 of the present embodiment can receive information that causes the defect of the memory system 1 by executing the command sequence mode Sq2.

The memory system 1 of the present embodiment can resolve the defect of the memory system 1, based on the received information.

FIG. 11 is a sequence diagram for illustrating the command sequence mode Sq2 executed in the memory system 1 of the present embodiment. In the description below, FIGS. 1 to 10 mentioned above will also be referred to as appropriate.

<Q30a, Q31a>

As shown in FIG. 11, the host device 5 sends the firmware update command HCMDfwup and the command sequence file IPFflg<1> to the memory system 1 of the present embodiment, as in the example shown in FIG. 10.

The command sequence file IPFflg<1> includes the identification flag FLG<1> and one or more commands (e.g., private commands used by a vendor) SCMDx.

A plurality of commands SCMDx may be grouped within the command sequence file IPFflg<1> such that the commands SCMDx can be executed in a specific order. The command sequence file IPFflg<1> is created by the host device 5 or by the server 900.

As in the above-described embodiments, the memory system 1 of the present embodiment receives the FW update command HCMDfwup and the command sequence file IPFflg<1>.

<Q32 to Q47>

As in the above-described embodiments, when the memory system 1 receives the FW update command HCMDfwup, the execution unit 103 starts executing various processes and operations in response to the instructions (S0 to S2 in FIG. 9) of the FW update command HCMDfwup obtained by the analysis unit 102 (Q33 to Q35).

As shown in S10 in FIG. 9, the execution unit 103 confirms the identification flag FLG of the input file IPF stored in the data buffer 122 (Q36).

When the identification flag FLG has a value (<1>) indicative of the command sequence file IPFflg<1> (Yes in S11 in FIG. 9), the execution unit 103 (or the CPU 101) executes various processes and operations in the command sequence mode Sq2, using the commands SCMDx and data DT included in the command sequence file IPFflg<1>.

As shown in S20 in FIG. 9, the execution unit 103 sets the execution flag FLGexe to the on state, based on the confirmation result of the identification flag FLG (F1).

In the present embodiment, the analysis unit 102 and the execution unit 103 execute a plurality of commands SCMDx in a specific order (Q38 to Q47).

In the processor 100, the CPU 101, the analysis unit 102 and the execution unit 103 repeat the above operation until all of the plurality of commands SCMDx in the command sequence file IPFflg<1> have been executed.

<Q48>

After all commands SCMDx of the command sequence file IPFflgc<1> have been executed, the execution unit 103 outputs a response RESsq. By doing so, the response RESsq according to the firmware update command HCMDfwup (the command sequence mode Sq2) is transferred from the memory system 1 to the host device 5.

The response RES allows the host device 5 to detect the execution result of the command sequence file IPFflg<1>.

For example, the response RESsq includes information (log data) indicative of how results of various processes and operations in the memory system 1 are before the execution of the command sequence file IPFflg<1> or during the execution of the command sequence file IPFflg<1>, and/or information indicative of the execution results of the commands in the command sequence file IPFflg<1>.

As a result, the host device 5 can receive the log data on the memory system 1 in the command sequence mode Sq2.

<Q90, Q91, 92>

The host device 5 analyzes the state of the memory system 1, based on the response RESsq and the received log data.

The host device 5 can verify the cause of a defect of the memory system 1 (e.g., a system error) by the analysis process Q90 of the log data.

As a result, the host device 5 can form data DTz for resolving the defect (e.g., an update program or a patch file).

The server 900 may execute various processes Q91 for analyzing the log data and verifying the defect of the memory system 1. In this case, the host device 5 transfers a file including the log data to the server 900 via the network.

Thus, the server 900 can form data DTz to resolve the defect by performing the process Q91.

The server 900 can provide the data DTz formed by the process Q92 to the host device 5 and the memory system 1.

The server 900 can provide information on the defect to the host device 5 (the user of the host device 5 or the memory system 1), based on the data obtained by executing the command sequence file IPFflg<1>.

<Q95>

The host device 5 uses data DTz to resolve the defect of the memory system 1.

For example, the host device 5 sends the command sequence file IPFflg<1>, which includes the command SCMD, the identification flag FLG<1> and update data DTz, to the memory system 1. The memory system 1 executes processes using the update data DTz, based on the command sequence mode Sq2. The memory system 1 sends the process result obtained with the update data DTz to the host device 5 as a response (not shown). The host device 5 receives the response.

As a result, the defect in the memory system 1 is resolved.

As described above, by the command sequence mode Sq2, the memory system 1 of the present embodiment is able to receive logs of various processes and operations in the memory system 1, based on the command sequence file IPFflg<1>.

Based on the analysis result of the received logs, the defect in the memory system 1 is resolved.

Therefore, the memory system 1 of the third embodiment can improve the functions (quality, characteristics, reliability, etc.) of the memory system 1.

### (4) Others

The process flow shown in FIG. 9, which includes the plurality of processes shown in FIGS. 6 to 8 described in connection with the above-described embodiments, may be executed by a program.

For example, a program (software) in which a program code corresponding to each process of FIGS. 6 to 9 is described is stored in a recording medium. The recording medium including the program is mounted on hardware. The program in the recording medium is executed on the hardware.

The program used in the memory system 1 of the present embodiment may be provided to other hardware via a network such as the Internet or an intranet.

In this manner, the control method of the memory system 1 of the present embodiment can be executed as a program stored in the recording medium.

In connection with the above-described embodiments, reference was made to an example in which the device (system) that executes the above-mentioned various processes and operations is a memory system. However, the device (system) that executes the above-mentioned processes and operations may be a system (or a device) other than the memory system. For example, the system 1 of the present embodiment can be realized as an information communication system or a network system.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory device; and
a controller connectable to a host device and configured to control the memory device in accordance with a firmware,
wherein the controller is configured to:
receive a first command relating to the controlling of the memory device and a first file including a first flag from the host device;
execute a first sequence in accordance with a content of the first file; and
after executing the first sequence, send a response including a notification of completion of the first sequence to the host device;
wherein the first sequence includes:
a first operation of executing update of the firmware when the first flag has a first value; and
a second operation of sequentially executing a plurality of second commands included in the first file when the first flag has a second value different from the first value.

2. The system according to claim 1, wherein the controller is further configured to:
set a second flag indicative of a state of execution of the plurality of second commands to a third value when the second operation is executed; and
set the second flag to a fourth value different from the third value when the executing of the second operation is completed.

3. The system according to claim 1, wherein the controller is further configured to:
receive a third command relating to the controlling of the memory device from the host device;
execute a second sequence in accordance with the third command; and
after executing the second sequence, send a response including a notification of completion of the second sequence to the host device;
wherein the second sequence includes any of a third operation of writing data to the memory device, a fourth operation of reading data from the memory device, and a fifth operation of erasing data from the memory device.

4. The system according to claim 1, wherein
the plurality of second commands include any of a command for debugging of the memory system, a command for receiving a log of the memory system, and a command for initializing the memory system.

5. The system according to claim 1, wherein:
the controller includes a processor; and
the firmware is executed by the processor.

6. The system according to claim 1, wherein the controller is configured to communicate with the host device based on a specific interface standard, and
the first command is a public command defined by the specific interface standard and the second command is a private command defined by the specific interface standard.

7. The system according to claim 1, wherein
the memory device is NAND flash memory.

8. A controlling method of a memory system including a memory device, the memory system being connectable to a host device and configured to control the memory device in accordance with a firmware, the method comprising:
receiving a first command relating to the controlling of the memory device and a first file including a first flag from the host device;
executing a first sequence in accordance with a content of the first file; and
after executing the first sequence, sending a response including a notification of completion of the first sequence to the host device;
wherein the first sequence includes:
a first operation of executing update of the firmware when the first flag having a first value; and
a second operation of sequentially executing a plurality of second commands included in the file when the first flag having a second value different from the first value.

9. The method according to claim 8, further comprising:
setting a second flag indicative of a state of execution of the plurality of second commands to a third value when the second operation is executed; and
setting the second flag to a fourth value different from the third value when the execution of the second operation is completed.

10. The method according to claim 8, further comprising:
receiving a third command relating to the controlling of the memory device from the host device;
executing a second sequence in accordance with the third command; and
after executing the second sequence, sending a response including a notification of completion of the second sequence to the host device;
wherein the second sequence includes any of a third operation of writing data to the memory device, a fourth operation of reading data from the memory device, and a fifth operation of erasing data from the memory device.

11. The method according to claim 8, wherein
the plurality of second commands include any of a command for debugging of the memory system, a command for receiving a log of the memory system, and a command for initializing the memory system.

12. The method according to claim 8, wherein:
the memory system includes a processor; and
the firmware is executed by the processor.

13. The method according to claim 8, wherein the memory system is configured to communicate with the host device based on a specific interface standard, and the first command is a public command defined by the specific interface standard and the second command is a private command defined by the specific interface standard.

14. The method according to claim 8, wherein
the memory device is NAND flash memory.

15. A host device connectable to a memory system including a memory device, the memory system being configured to control the memory device in accordance with a firmware, the host device comprising:
a processor configured to generate a first command relating to the controlling of the memory system and a first file including a flag; and
an interface circuit configured to send the first command and the first file to the memory system,
wherein:
the processor is configured to:
set a first value to the flag when causing the memory system to execute update of the firmware in accordance with the first command; and
set a second value different from the first value to the flag when causing the memory system to sequentially execute a plurality of second commands included in the first file in accordance with the first command.

16. The device according to claim 15, wherein
the processor is configured to generate a third command relating to the controlling of the memory system, and the third command is different from the first command and includes any of a fourth command for writing data to the memory device, a fifth command for reading data from the memory device, and a sixth command for erasing data from the memory device.

17. The device according to claim 15, wherein
the plurality of second commands include any of a command for debugging of the memory system, a command for receiving a log of the memory system, and a command for initializing the memory system.

18. The device according to claim 15, wherein the processor is configured to:
receive a response including a notification of completion of the first command from the memory system; and
analyze a state of the memory system based on the received response.

19. The device according to claim 15, wherein the interface circuit is configured to communicate with the memory system based on a specific interface standard, and the first command is a public command defined by the specific interface standard and the second command is a private command defined by the specific interface standard.

20. The device according to claim 15, wherein
the memory device is NAND flash memory.
